(19) United States
(12) Patent Application Publication
(10) Pub. No.: US 2013/0020719 A1
(43) Pub. Date: Jan. 24, 2013

(54) MICROELECTRONIC DEVICES INCLUDING THROUGH SILICON VIA STRUCTURES HAVING POROUS LAYERS

(71) Applicants: Eun-Ji Jung, Hwaseong-si (KR); Tsukasa Matsuda, Seongnam-si (KR); Jongho Yun, Suwon-si (KR); Jongjin Lee, Seoul (KR); Gilheyun Choi, Seoul (KR); Seung-Wook Choi, Metropolitan City (KR)

(72) Inventors: Eun-Ji Jung, Hwaseong-si (KR); Tsukasa Matsuda, Seongnam-si (KR); Jongho Yun, Suwon-si (KR); Jongjin Lee, Seoul (KR); Gilheyun Choi, Seoul (KR); Seung-Wook Choi, Metropolitan City (KR)

(73) Assignee: Samsung Electronics Co., Ltd.

(21) Appl. No.: 13/421,388

(22) Filed: Mar. 15, 2012

(30) Foreign Application Priority Data
Jul. 18, 2011 (KR) 10-2011-0071010

(51) Int. Cl. H01L 23/498

(52) U.S. Cl. 257/774; 257/E23.067

(57) ABSTRACT

A microelectronic device includes a substrate including a via hole extending therethrough, a porous layer on sidewalls of the via hole, and a conductive via electrode extending through the via hole between the sidewalls thereof. The porous layer includes a plurality of pores therein that reduce a dielectric constant of the porous layer. Related fabrication methods are also discussed.

### CROSS-REFERENCE TO RELATED APPLICATIONS

This U.S. non-provisional patent application claims priority under 35 U.S.C. §119 from Korean Patent Application No. 10-2011-0071010, filed on Jul. 18, 2011, the entirety of which is hereby incorporated by reference herein.

### BACKGROUND

The present inventive concept relates to semiconductor devices and methods of fabricating the same and, more particularly, to microelectronic semiconductor devices having through silicon via (TSV) electrodes and methods of forming the same.

In the electronics industry, low cost electronic devices have been increasingly demanded with the development of lighter, smaller, faster, more multi-function and high performance in more sophisticated electronic systems. In response to such a demand, multi-chip stacked package techniques and/or system in package techniques may be used.

In a multi-chip stacked package or a system in package, one or more functions of a plurality of semiconductor devices may be performed in a single semiconductor package. A multi-chip stacked package or a system in package may be thicker than a single chip package. However, a multi-chip stacked package or a system in package may have a similar size to the single chip package in terms of a planar surface area or ‘footprint’. Thus, a multi-chip stacked package or a system in package may be used in small and/or mobile devices with high performance requirements, for example, mobile phones, notebook computers, memory cards, and/or portable camcorders.

Multi-chip stacked package techniques or system in package techniques may be realized using through silicon via electrodes. However, the use of through silicon via electrodes may be associated with some problems, which may affect the performance of the devices in which they are used.

### SUMMARY

Exemplary embodiments of the inventive concept are directed to microelectronic devices and methods of forming the same.

According to some embodiments, a microelectronic device includes a substrate including a via hole extending therethrough, a porous layer on sidewalls of the via hole, and a conductive via electrode extending through the via hole between the sidewalls thereof. The porous layer includes a plurality of pores therein having respective dimensions such that the porous layer is mesoporous or macroporous. For example, the pores of the porous layer may have dimensions of at least about 10 nanometers.

In some embodiments, the pores of the porous layer may have respective diameters of about 10 nanometers to about 500 nanometers. In some embodiments, the pores may extend into the porous layer in a direction substantially perpendicular to the sidewalls of the via hole. In some embodiments, the respective diameters of the pores may decrease from portions of the porous layer adjacent the via electrode.

In some embodiments, the via hole may extend from a first surface of the substrate to a second surface of the substrate opposite the first surface. In some embodiments, the porous layer may have a non-uniform pore density that decreases from the first surface towards the second surface. In some embodiments, the porous layer may have a substantially uniform pore density throughout.

In some embodiments, the porous layer may be a porous insulating layer that surrounds the via electrode and separates the via electrode from the substrate. For example, the pores of the porous layer may extend completely therethrough to expose portions of the substrate along the sidewalls of the via hole. In some embodiments, the pores of the porous layer may further extend into the portions of the substrate along the sidewalls of the via hole.

In some embodiments, a via insulating layer may extend on sidewalls of the via electrode between the via electrode and the porous layer. The porous layer may have dielectric constant that is less than that of the via insulating layer. In some embodiments, the porous layer and the via insulating layer may respectively comprise a silicon oxide.

In some embodiments, the via insulating layer may be a first via insulating layer, and second via insulating layer may extend on the sidewalls of the via hole between the porous layer and the substrate. The porous layer may have dielectric constant that is less than that of the second via insulating layer. For example, in some embodiments, the pores may not extend completely through the porous layer, such that the second via insulating layer may be a portion of the porous layer through which the pores do not extend.

In some embodiments, the porous layer may include portions of the substrate that define the sidewalls of the via hole.

In some embodiments, at least one microelectronic component may be provided on a surface of the substrate outside the via hole. The at least one microelectronic component may be laterally spaced apart from the via electrode by about 5 micrometers or less.

In some embodiments, the via hole and the conductive via therein may be confined below the surface of the substrate including the at least one microelectronic component thereon.

In some embodiments, the device may include one or more insulating interlayers on the surface of the substrate including the at least one microelectronic component, and the via hole and the conductive via therein may extend through at least one of the one or more insulating interlayers.

In some embodiments, the conductive via electrode may include a barrier layer on the sidewalls of the via hole, and a conductive layer on the barrier layer. The barrier layer may include a material configured to reduce atomic diffusion of the conductive layer into the substrate. In some embodiments, the conductive via may include doped polysilicon or tungsten.

In some embodiments, a multi-chip module may include a module substrate and a first microelectronic device having a conductive via electrode structure as described herein on the module substrate. The via electrode may provide an electrical connection between the first microelectronic device and the module substrate. In some embodiments, the multi-chip module may include a second microelectronic device on the first microelectronic device, and the via electrode may provide an electrical connection between the second microelectronic device and the module substrate. In some embodiments, the multi-chip module may be a system in package (SIP), where one of the first and second microelectronic devices may be a memory device, and where the other of the first and second microelectronic devices may be a memory controller.

In some embodiments, an electronic system may include a processor, a memory, a user interface, and a bus configured to provide communication between the processor, the memory, and the user interface. At least one of the processor and the memory may include a microelectronic device having a conductive via electrode structure as described herein.

According to further embodiments, a microelectronic device includes a substrate including a via hole extending therethrough. Sidewalls of the via hole include a silicon oxide layer and a layer having a lower dielectric constant than that of the silicon oxide layer thereon. A conductive via electrode extends through the via hole between the sidewalls thereof such that the silicon oxide layer separates the via electrode from the layer having the lower dielectric constant.

In some embodiments, the layer having the lower dielectric constant may be a porous layer including a plurality of pores therein having respective pore sizes greater than those of the silicon oxide layer. The pores may be sized sufficiently to reduce the dielectric content of the porous layer to less than that of the silicon oxide layer.

In some embodiments, the porous layer may be a portion of the silicon oxide layer.

In some embodiments, the porous layer may be a portion of the substrate.

According to still further embodiments, a method of fabricating a microelectronic device includes forming a via hole extending into a substrate, forming a porous layer at sidewalls of the via hole, and forming a conductive via electrode in the via hole between the sidewalls thereof. The porous layer includes a plurality of pores therein having respective dimensions such that the porous layer is mesoporous or macroporous. For example, the pores of the porous layer may have dimensions of at least 10 nanometers.

In some embodiments, the pores of the porous layer may have respective diameters of about 10 nanometers to about 500 nanometers. In some embodiments, the pores may extend into the porous layer in a direction substantially perpendicular to the sidewalls of the via hole. In some embodiments, the respective diameters of the pores may decrease from portions of the porous layer adjacent the via electrode.

In some embodiments, forming the porous layer may include forming an insulating layer on the sidewalls of the via hole, and patterning the insulating layer to define the porous layer having the plurality of pores therein.

In some embodiments, patterning the insulating layer may include forming a porous mask layer on the insulating layer on the sidewalls of the via hole. The porous mask layer may have an etching selectivity with respect to the insulating layer, and the insulating layer may be etched using the porous mask layer as an etch mask to define the porous layer having the plurality of pores therein.

In some embodiments, the porous mask layer may be an amorphous carbon layer.

In some embodiments, the etching may be performed using a wet etch process, and the porous layer may have a substantially uniform pore density throughout.

In some embodiments, the etching may be performed using a dry etch process, and the porous layer may have a non-uniform pore density that decreases from the first surface of the substrate towards the second surface of the substrate through which the via hole extends.

In some embodiments, forming the porous mask layer may include forming a first mask layer the on the insulating layer on the sidewalls of the via hole, where the first mask layer may have etching selectivity with respect to the insulating layer, forming a porous second mask layer on the first mask layer on the sidewalls of the via hole, where the second mask layer may have etching selectivity with respect to the first mask layer, and etching the first mask layer using the porous second mask layer as an etch mask to define the porous mask layer.

In some embodiments, forming the porous second mask layer may include forming a diblock copolymer layer comprising two polymer chains on the first mask layer on the sidewalls of the via hole, heating the diblock copolymer layer to separate one of the two polymer chains, and selectively removing the one of the two polymer chains to define the porous second mask layer.

In some embodiments, forming the porous second mask layer may include forming a preliminary porous low-k dielectric layer on the first mask layer on the sidewalls of the via hole, and heating the preliminary porous low-k dielectric layer to define the porous second mask layer. For example, the preliminary porous low-k dielectric material may be a carbon-containing silicon oxide layer. In some embodiments, the pores in the porous second mask layer may be oriented randomly relative to the sidewalls of the via hole.

In some embodiments, forming the porous second mask layer may include forming a layer comprising a dielectric material and an amphiphilic polymer on the first mask layer on the sidewalls of the via hole, and selectively removing the amphiphilic polymer to define the porous second mask layer.

In some embodiments, forming the porous layer may include forming a porous mask layer having an etch selectivity with respect to the substrate on the sidewalls of the via hole, and etching portions of the substrate along the sidewalls of the via hole using the porous mask layer as an etch mask to define the plurality of pores in the portions of the substrate along the sidewalls of the via hole.

In some embodiments, patterning the insulating layer to define the porous layer may include patterning the insulating layer such that the plurality of pores extend completely therethrough to expose portions of the substrate along the sidewalls of the via hole. In some embodiments, patterning the insulating layer to define the porous layer may further include patterning the insulating layer such that the plurality of pores of further extend into the portions of the substrate along the sidewalls of the via hole.

In some embodiments, patterning the insulating layer to define the porous layer may include patterning the insulating layer such that the plurality of pores do not extend completely therethrough. Portions of the insulating layer through which the pores extend may define the porous layer, and portions of the insulating layer through which the plurality of pores do not extend may define a second via insulating layer having a dielectric constant greater than the porous layer.

In some embodiments, before forming the via electrode, a via insulating layer may be formed on the porous layer on the sidewalls of the via hole. The porous layer may have a dielectric constant that is less than that of the via insulating layer.

In some embodiments, at least one microelectronic component may be formed on a surface of the substrate. The at least one microelectronic component may be laterally spaced apart from the via electrode by about 5 micrometers or less.

In some embodiments, after forming the via electrode, a first insulating interlayer may be formed on the surface of the substrate including the at least one microelectronic component thereon such that the via electrode may be confined below the surface of the substrate.

In some embodiments, before forming the via hole, at least one insulating interlayer may be formed on the surface of the substrate including the at least one microelectronic component thereon. The via hole may be formed to extend through the at least one insulating interlayer and into the substrate.

According to some embodiments, a semiconductor device comprises a substrate including a via hole extending from a first surface of the substrate toward a second surface of the substrate opposite to the first surface, a through silicon via electrode in the via hole, and a porous layer between the substrate and the through silicon via electrode.

In some embodiments, the porous layer may include a porous first silicon oxide layer, and the semiconductor device may further comprise a non-porous second silicon oxide layer between the porous layer and the through silicon via electrode.

In some embodiments, the semiconductor device may further comprise a non-porous third silicon oxide layer between the porous layer and the substrate.

In some embodiments, the porous layer may include a porous SiCOH layer, and the semiconductor device may further comprise a non-porous silicon oxide layer between the porous layer and the through silicon via electrode.

In some embodiments, the porous layer may include a single crystalline silicon layer having a plurality of pores therein, and the semiconductor device may further comprise a non-porous silicon oxide layer between the porous layer and the through silicon via electrode.

According to further embodiments, a semiconductor device comprises a substrate including a via hole extending from a first surface of the substrate toward a second surface of the substrate opposite to the first surface, a through silicon via electrode in the via hole, and an insulating layer between the through silicon via electrode and the substrate. The insulating layer includes a silicon oxide layer and a low-k dielectric layer having a dielectric constant which is less than that of the silicon oxide layer.

According to still further embodiments, a method comprises forming a via hole extending from a first surface of a substrate toward a second surface of the substrate opposite to the first surface, forming a first porous layer at a sidewall of the via hole, and filling the via hole surrounded by the first porous layer with a conductive layer to form a through silicon via electrode.

In some embodiments, forming the first porous layer may comprise forming a first insulating layer on the sidewall of the via hole and forming a plurality of pores in the first insulating layer.

In some embodiments, forming the plurality of pores in the first insulating layer may comprise forming a mask layer having an etch selectivity with respect to the first insulating layer on the first insulating layer, forming a second porous layer on the mask layer, etching the mask layer using the second porous layer as an etch mask to form a plurality of pores in the mask layer, and etching the first insulating layer using the mask layer having the pores as an etch mask.

In some embodiments, forming the second porous layer may comprise forming a SiCOH layer on the mask layer, and heating the SiCOH layer to form a plurality of holes in the SiCOH layer.

In some embodiments, forming the second porous layer may comprise forming a diblock copolymer having two distinct polymer chains on the mask layer, and selectively removing one of the polymer chains constituting the diblock copolymer to form a block layer having a plurality of holes.

In some embodiments, forming the first porous layer may comprise forming a diblock copolymer having two distinct polymer chains on the first insulating layer, selectively removing one of the polymer chains constituting the diblock copolymer to form a block layer having a plurality of holes, and etching the first insulating layer using the block layer having the holes as an etch mask.

In some embodiments, forming the first porous layer may comprise forming a SiCOH layer on the sidewall of the via hole, and annealing the SiCOH layer to form a plurality of holes in the SiCOH layer.

According to yet further embodiments, a method comprises forming a via hole extending from a first surface of a silicon substrate toward a second surface of the silicon substrate opposite to the first surface, etching a sidewall of the via hole to form a porous silicon layer in the sidewall of the via hole, forming a first insulating layer on the porous silicon layer, and forming a through silicon via electrode filling the via hole surrounded by the first insulating layer.

Other devices and/or methods according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

The inventive concept will become more apparent in view of the attached drawings and accompanying detailed descriptions.

FIG. 1 is a cross sectional view illustrating a semiconductor device according to an embodiment of the inventive concept.

FIG. 2 is an enlarged view of a portion ‘A’ of FIG. 1.

FIGS. 3 to 10 are cross sectional views illustrating an example of a method of forming a semiconductor device according to an embodiment of the inventive concept.

FIG. 11 is a cross sectional view illustrating another example of a method of forming a semiconductor device according to an embodiment of the inventive concept.

FIGS. 12 and 13 are cross sectional views illustrating another example of a method of forming a semiconductor device according to an embodiment of the inventive concept.

FIG. 14 is a cross sectional view illustrating a semiconductor device according to another embodiment of the inventive concept.

FIGS. 15 to 19 are cross sectional views illustrating a method of forming a semiconductor device according to another embodiment of the inventive concept.

FIG. 20 is a cross sectional view illustrating a semiconductor device according to still another embodiment of the inventive concept.

FIG. 21 is a cross sectional view illustrating a semiconductor device according to yet another embodiment of the inventive concept.

FIG. 22 is an enlarged view of a portion ‘B’ of FIG. 21.

FIGS. 23 to 26 are cross sectional views illustrating a method of forming a semiconductor device according to yet another embodiment of the inventive concept.

FIGS. 27 to 29 illustrate semiconductor packages according to embodiments of the inventive concept.

FIG. 30 is a plan view illustrating package modules according to embodiments of the inventive concept.

FIG. 31 is a schematic block diagram illustrating a memory card according to embodiments of the inventive concept.

FIG. 32 is a schematic block diagram illustrating an electronic system according to embodiments of the inventive concept.

FIG. 33 is a schematic view illustrating a mobile phone to which an electronic system according to embodiments of the inventive concept is applied.

### DETAILED DESCRIPTION OF THE EMBODIMENTS

The inventive concept will now be described more fully hereinafter with reference to the accompanying drawings, in which exemplary embodiments of the inventive concept are shown. It should be noted, however, that the inventive concept is not limited to the following exemplary embodiments, and may be implemented in various different forms. Rather, these embodiments are provided so that this disclosure will be thorough and complete, and will fully convey the scope of the invention to those skilled in the art. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

It will be understood that when an element such as a layer, region or substrate is referred to as being “on” or “connected (or coupled) to” another element, it can be directly on or connected (or coupled) to the other element or intervening elements may be present. In contrast, the terms “directly on” “directly connected,” or “directly coupled” mean that there are no intervening elements. Similarly, it will be understood that when an element such as a layer, region or substrate is referred to as being “between” two different elements, it can be directly interposed between the two different elements without any intervening element or intervening elements may be present therebetween. In contrast, the term “directly between” means that there are no intervening elements.

Moreover, it will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of the present inventive concept explained and illustrated herein include their complementary counterparts. The same reference numerals or the same reference designators denote the same elements throughout the specification.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is inverted, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof. As used herein, the term “and/or” includes any and all combinations of one or more of the associated listed items.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein, but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

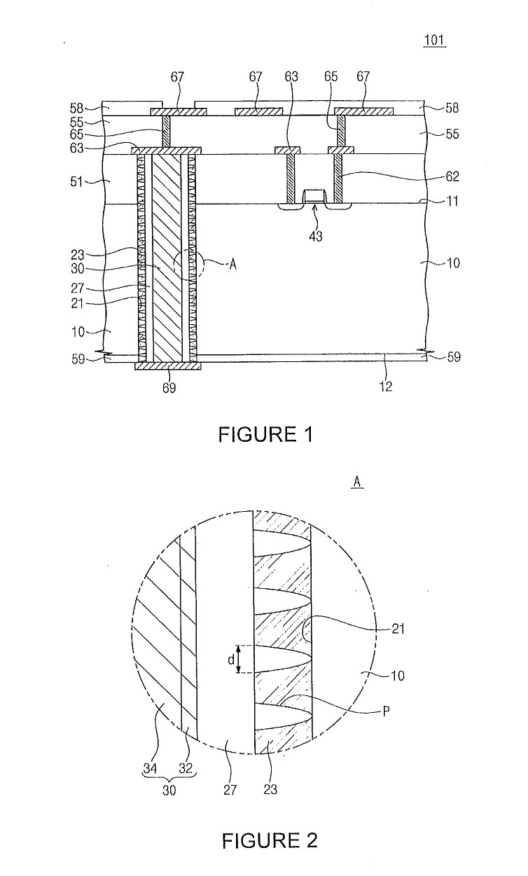

A semiconductor device 101 according to an embodiment of the inventive concept will be described hereinafter. FIG. 1 is a cross sectional view illustrating a semiconductor device according to an embodiment of the inventive concept, and FIG. 2 is an enlarged view of a portion ‘A’ of FIG. 1.

Referring to FIGS. 1 and 2, the semiconductor device 101 may include a substrate 10 having a first surface 11 and a second surface 12 opposite to the first surface 11. The substrate 10 may be doped with impurities, for example, P-type impurities.

A microelectronic component or semiconductor element 43 may be disposed on and/or under the first surface 11 of the substrate 10. The semiconductor element 43 may correspond to a transistor in some embodiments. For example, the semiconductor element 43 may be an NMOS transistor, a PMOS transistor or a bipolar transistor. A first interlayer insulating layer 51 may be formed on the first surface 11 to cover the semiconductor element 43. The first interlayer insulating layer 51 may include a silicon oxide layer.

A via hole 21 may be formed to penetrate the substrate 10 and the first interlayer insulating layer 51. The via hole 21 may extend from the first interlayer insulating layer 51 on the first surface 11 toward the second surface 12. The via hole 21 may have a depth of about 50 μm (micrometers) in some embodiments. The depth of the via hole 21 may vary according to a design rule of the semiconductor device 101 or required characteristics of the semiconductor device 101.

A though silicon via electrode 30 (more generally referred to herein as a conductive via electrode) may fill the via hole 21. The through silicon via electrode 30 may be exposed at the second surface 12. The through silicon via electrode 30 may extend toward a top surface of the first interlayer insulating layer 51 opposite to the first surface 11 of the substrate 10. A porous layer 23 and a via hole insulating layer 27 may be disposed between the through silicon via electrode 30 and a sidewall of the via hole 21. The porous layer 23 may have a plurality of voids or pores P therein. The porous layer 23 may have a greater volume of voids (e.g., a greater porosity) than the surrounding substrate 10. The pores P may extend in a substantially perpendicular direction to the sidewall of the via hole 21. The pores P may extend completely through the porous layer 23 and may directly contact the sidewall of the via hole 21. That is, the pores P may expose portions of the sidewall of the via hole 21. The pores P may further extend into the substrate 10. The density of the pores P may be gradually reduced from the first surface 11 toward the second surface 12. The pores P may have a size or dimension ‘d’ (for example, a diameter) of about several ten nanometers (nm) to several hundred nanometers. As such, the porous layer 23 may be described herein as mesoporous (e.g., having pores with dimensions of between about 2 nm to about 50 nm) and/or macroporous (e.g., having pores with dimensions of greater than about 50 nm). The pores may be sized sufficiently to reduce a dielectric content of the porous layer 23, for example, to less than that of a silicon oxide layer in some embodiments. For example, the pores P may have a dimension of at least about 10 nm to about 500 nm in some embodiments. Also, as shown in FIG. 1, the diameter d of the pores P may decrease from portions of the porous layer 23 adjacent the via electrode 30 toward the substrate 10. The porous layer 23 may be a silicon oxide layer, a silicon nitride layer, or a combination thereof. In particular embodiments, the porous layer 23 may be a porous silicon oxide layer. The via hole insulating layer 27 may be a silicon oxide layer, a silicon nitride layer or a combination thereof. Also, the via hole insulating layer 27 may be a non-porous silicon oxide layer.

The though silicon via electrode 30 may include a barrier layer 32 and a conductive layer 34 on the barrier layer 32. For example, the conductive layer 34 may be surrounded by the barrier layer 32. The barrier layer 32 may include a titanium layer, a titanium nitride layer, a tantalum layer, a tantalum nitride layer, a ruthenium layer, a cobalt layer, a manganese layer, a tungsten nitride layer, a nickel layer, a nickel boride layer, and/or a double layer such as a titanium/titanium nitride (Ti/TiN) layer. The barrier layer 32 can reduce or prevent metal atoms in the conductive layer 34 from diffusing into the substrate 10. The conductive layer 34 may include a metal layer. In some embodiments, the conductive layer 34 may include a silver layer, a gold layer, a copper layer, an aluminum layer, a tungsten layer or an indium layer.

First contacts 62 may penetrate the first interlayer insulating layer 51 to be connected to impurity regions of the semiconductor element 43, for example, source/drain regions of a MOS transistor.

First pads 63 may be disposed on the first interlayer insulating layer 51. The first pads 63 may be electrically connected to the through silicon via electrode 30 and/or the first contacts 62. A second interlayer insulating layer 55 may be formed on the first interlayer insulating layer 51 and the first pads 63. The second interlayer insulating layer 55 may include a silicon oxide layer. Second pads 67 may be formed on the second interlayer insulating layer 55. The second pads 67 may be connected to the first pads 63 via second contacts 65 formed in the second interlayer insulating layer 55.

A first passivation layer 58 may be disposed to cover the second interlayer insulating layer 55 and to expose at least one of the second pads 67. The first passivation layer 58 can protect an integrated circuit including the semiconductor element 43 from an external environment. The first passivation layer 58 may be formed of a silicon oxide layer, a silicon nitride layer or a combination thereof. The pads 63 and 67 may be formed of an aluminum layer or a copper layer. The contacts 62 and 65 may be formed of an aluminum layer or a tungsten layer.

A second passivation layer 59 may be formed on the second surface 12 of the substrate 10 opposite to the first surface 11. A third pad 69 may be formed on the second passivation layer 59, and the third pad 69 may be connected to the through silicon via electrode 30. The second passivation layer 59 may be formed of a silicon oxide layer, a silicon nitride layer or a combination thereof. The third pad 69 may be formed of a copper layer. The first to third pads 63, 67 and 69 may extend to become wirings.

In general, the semiconductor element 43 or other microelectronic device(s) formed adjacent the through silicon via electrode 30 may exhibit poor electrical characteristics and poor reliability. This may be due to a thermal stress caused by a coefficient of thermal expansion mismatch between the metal through silicon via electrode 30 and the semiconductor substrate 10. Thus, a keep-out zone (KOZ) in which formation of the semiconductor element 43 is forbidden or should be avoided may exist in the substrate 10. Semiconductor devices having a conventional through silicon via electrode structure have a keep-out zone (KOZ) of at least about 5˜20 μm. That is, in conventional semiconductor devices, the semiconductor element should be formed to be spaced apart from the conventional through silicon via (TSV) electrode by at least 5˜20 μm.

However, according to some embodiments of the present inventive concept, the porous layer 23 is disposed between the semiconductor element 43 and the through silicon via electrode 30. The porous layer 23 can alleviate the above-described thermal stress of the through silicon via electrode 30. Thus, in the event that the porous layer 23 is formed to surround the through silicon via electrode 30, the porous layer 23 can reduce or prevent the electrical characteristics and the reliability of the semiconductor element 43 from degrading, even though the semiconductor element 43 or other microelectronic device is formed at a location which is spaced apart from the through silicon via electrode 30 by a distance of about 0.5 μm to about 20 μm. Therefore, it may be possible to reduce the keep-out zone (KOZ) from through silicon via electrode 30 to about 5 μm or less, or even to about 0.5 μm or less in some embodiments. That is, the keep-out zone (KOZ) from the through silicon via electrode 30 can be reduced due to the presence of the porous layer 23. Consequently, the integration density of the semiconductor device can be increased.

Further, since the porous layer 23 has a plurality of pores P, the porous layer 23 has a dielectric constant which is lower than that of a conventional via hole insulating layer, such as a non-porous insulating layer (for example, a silicon oxide or silicon nitride layer). Thus, parasitic capacitance between the through silicon via electrode 30 and wirings (and/or the substrate) adjacent the through silicon via electrode 30 can be reduced without an increase in thickness of the via hole insulating layer 27. As such, the electrical characteristics and the reliability of the semiconductor element 43 can be improved due to the presence of the porous layer 23.

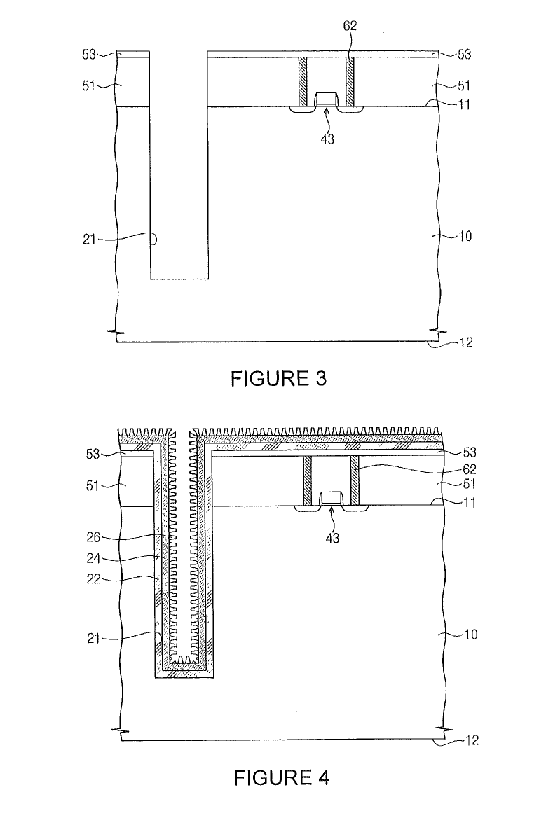

Examples of methods of fabricating a semiconductor device 101 according to some embodiments will be now described. FIGS. 3 to 10 are cross sectional views illustrating an example of a method of forming a semiconductor device according to an embodiment of the inventive concept.

Referring to FIG. 3, a substrate 10 including a first surface 11 and a second surface 12 opposite to the first surface 11 may be provided. The substrate 10 may be doped with impurities, for example, P-type impurities.

A microelectronic component or semiconductor element 43 may be formed on and/or under the first surface 11 of the substrate 10. The semiconductor element 43 may correspond to a transistor. For example, the semiconductor element 43 may be an NMOS transistor, a PMOS transistor or a bipolar transistor. FIG. 3 illustrates the semiconductor element 43 as a single transistor. However, the number of semiconductor elements 43 is not limited to one. For example, the number of the semiconductor elements 43 may be two or more in some embodiments.

A first interlayer insulating layer 51 may be formed on the first surface 11 to cover the semiconductor element 43. The first interlayer insulating layer 51 may include a silicon oxide layer. First contacts 62 may be formed to penetrate the first interlayer insulating layer 51. The first contacts 62 may be formed of a tungsten layer. The first contacts 62 may be electrically connected to impurity regions of the semiconductor element 43, for example, source/drain regions of a MOS transistor. An etch stop layer 53 may be formed on the first interlayer insulating layer 51. The etch stop layer 53 may include a silicon nitride layer.

A mask pattern may be formed on the etch stop layer 53. The etch stop layer 53, the first interlayer insulating layer 51 and the substrate 10 may be etched using the mask pattern as an etch mask, thereby forming a via hole 21. The via hole 21 may be formed using a drilling process, a Bosch etching process or a steady state etching process. The via hole 21 may penetrate the etch stop layer 53 and the first interlayer insulating layer 51, and the via hole 21 may extend from the first surface 11 toward the second surface 12. The via hole 21 may be formed not to penetrate the substrate 10. In some embodiments, the via hole 21 may be formed to have a depth of about 50 μm. The depth of the via hole 21 may vary according to a design rule of the semiconductor device 101 or desired characteristics of the semiconductor device 101.

Referring to FIG. 4, the mask pattern may be removed. A buffer layer 22 may be formed on the first surface 11 and in the via hole 21. The buffer layer 22 may be formed to cover a sidewall of the via hole 21. The buffer layer 22 may include a silicon oxide layer, a silicon nitride layer or a combination thereof. In particular embodiments, the buffer layer 22 may be a silicon oxide layer. The buffer layer 22 may be formed using an ozone (O₃) tetra-ethyl-ortho-silicate (TEOS) chemical vapor deposition (CVD) process.

A first mask layer 24 may be formed on the buffer layer 22. The first mask layer 24 may have an etch selectivity with respect to the buffer layer 22. The first mask layer 24 may be, for example, an amorphous carbon layer. The amorphous carbon layer may be formed using an atomic layer deposition (ALD) process or a chemical vapor deposition (CVD) process.

A porous second mask layer 26 may be formed on the first mask layer 24. The porous second mask layer 26 may have a plurality of pores therein and may have an etch selectivity with respect to the first mask layer 24. The pores may have a size (e.g., a diameter) of about several ten nanometers to several hundred nanometers.

The porous second mask layer 26 may be formed using several methods. In one method, a diblock copolymer may be used in formation of the porous second mask layer 26. The diblock copolymer consists of two distinct polymer chains covalently bound at one end. One of the polymers constituting the diblock copolymer is selectively removed to form a block having a plurality of holes. Consequently, the porous second mask layer 26 may be formed.

In particular embodiments, the diblock copolymer may include polystyrene-block-poly(methyl methacrylate) (PS-b-PMMA). The PS-b-PMMA has a chemical structure that the polystyrene (PS) is combined with the poly(methyl meth acrylate) (PMMA) by a covalent bond. The PS-b-PMMA may be formed on the first mask layer (24) using a spin coating process. If the PS-b-PMMA is heated at a temperature exceeding the glass transition temperature (e.g., about 200° C.) for about forty eight hours or more, the PS-b-PMMA may be separated into micro phases to form cylinder-shaped PMMA blocks. Each of the cylinder-shaped PMMA blocks may have a diameter of about several ten nanometers. The PMMA blocks may be selectively decomposed by UV exposure. The decomposed PMMA blocks may be removed using a mixture of acetic acid (CH₃COOH) and de-ionized water. As a result of removal of the decomposed PMMA blocks, a polystyrene block having holes may be left on the first mask layer 24. The holes of the polystyrene block may have a size of about several ten nanometers. The size and distribution of the holes in the polystyrene block may depend on a ratio of molecular weight of the polystyrene (PS) and the PMMA.

In another method, a porous low-k dielectric layer may be used in formation of the porous second mask layer 26. For example, a silicon oxide layer containing carbon may be formed on the first mask layer 24. The carbon and the silicon in the silicon oxide layer may be combined with each other to make a SiO₂ network structure of the silicon oxide layer into a cage-like structure having a less dense structure than the silicon oxide layer. The silicon oxide layer having the cage-like structure may correspond to a SiCOH layer. Trimethylsilane ((CH3)3—Si—H) 3MS, tetramethylsilane ((CH3)4—Si) 4MS, or vinyltrimethylsilane (CH2═CH—Si(CH3)3) VTMS may be used as a precursor of the SiCOH layer. An oxidizer, for example, a hydrogen peroxide gas containing oxygen may be used in oxidation of the precursor. The silicon oxide layer containing carbon may be deposited using a plasma enhanced chemical vapor deposition (PECVD) process. The silicon oxide layer containing carbon may be transformed into the porous second mask layer 26, i.e., the porous SiCOH (p-SiCOH) layer by a heating process. The porous second mask layer 26 may have a plurality of pores. The pores may have a size (e.g., a diameter) of about several ten nanometers to several hundred nanometers.

In still another method, an amphiphilic polymer may be used in formation of the porous second mask layer 26. In particular, a layer including a dielectric material and an amphiphilic polymer may be formed on the first mask layer 24. For example, a layer including silicon oxide (as the dielectric material) and the amphiphilic polymer may be deposited by plasma-enhanced chemical vapor deposition (PECVD). The amphiphilic polymer may react with the silicon oxide to provide controlled self-assembly, in which a hydrophilic portion or end of the polymer attracts the silicon of the silicon oxide layer, thereby forming pores in the silicon oxide layer. As such, the deposited layer has a less dense structure than silicon oxide. The amphiphilic polymer may then be removed (for example, using a chemical solution) to define the porous second mask layer 26.

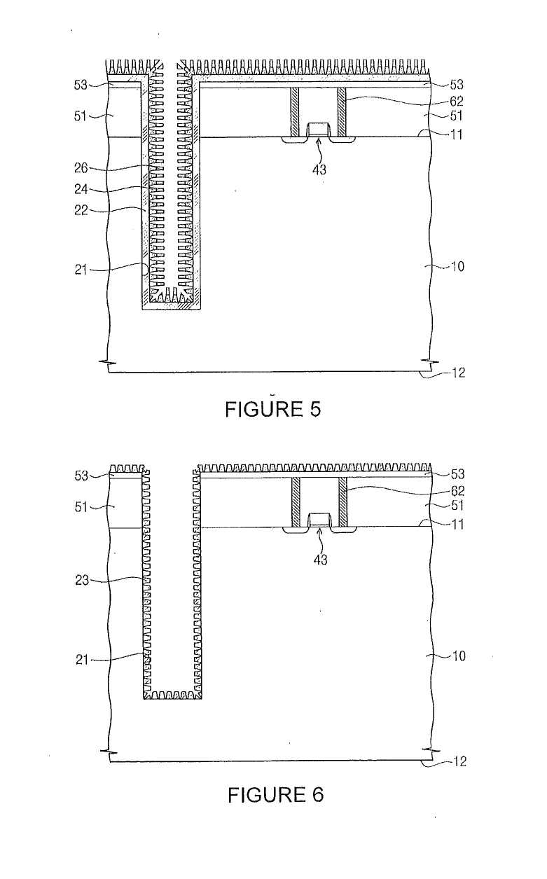

Referring to FIG. 5, the first mask layer 24 may be etched using the porous second mask layer 26 as an etch mask, thereby forming a plurality of pores in the first mask layer 24. The pores may extend in a direction that is substantially perpendicular to a sidewall of the via hole 21. The pores in the first mask layer 24 may have a size (e.g., a diameter) of about several ten nanometers to several hundred nanometers, as discussed above with reference to FIGS. 1 and 2.

Etching the first mask layer 24 may be performed using an isotropic etching process, an anisotropic etching process, or a combination thereof. In addition, the etching process for etching the first mask layer 24 may include a wet etching process, a dry etching process, or a combination thereof. In some embodiments, if the first mask layer 24 is etched using a wet etching process, the wet etchant may be supplied in a substantially uniform manner throughout an inside region of the via hole 21. Thus, the distribution or density of the pores formed in the first mask layer 24 may be substantially uniform throughout the inside region of the via hole 21. Additionally or alternatively, if the first mask layer 24 is etched using a dry etching process, an etching gas used in the dry etching process may not be sufficiently supplied into a lower region of the deep and narrow via hole 21 as the etch time elapses. Thus, the density of the pores may be gradually reduced from the first surface 11 toward the second surface 12.

Referring to FIG. 6, the buffer layer 22 may be etched using the porous first mask layer 24 having the plurality of pores as an etch mask, thereby forming a porous layer 23 having a plurality of pores. The pores in the porous layer 23 may expose portions of the sidewall of the via hole 21. The pores in the porous layer 23 may further extend into the substrate 10. The porous first and second mask layers 24 and 26 may be then removed.

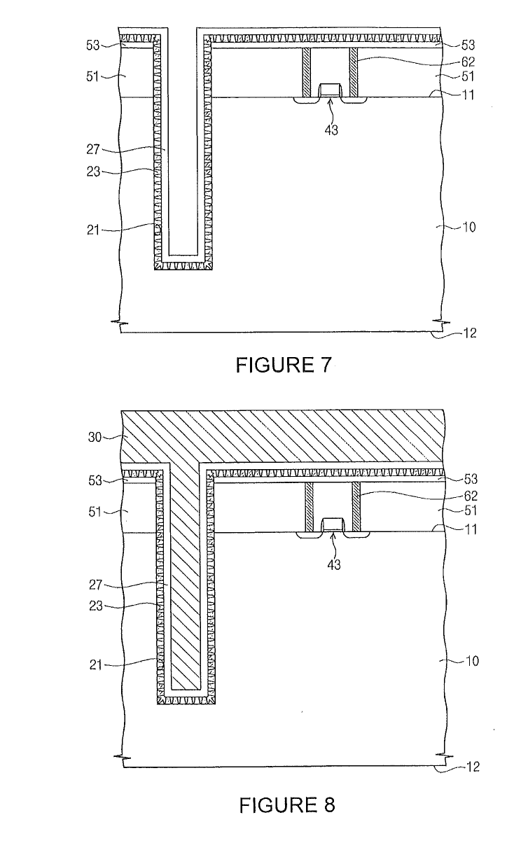

Referring to FIG. 7, a via hole insulating layer 27 may be formed on the porous layer 23. The via hole insulating layer 27 may help a formation process of a conductive layer (e.g., a copper layer) for the through silicon via electrode in a subsequent process. The via hole insulating layer 27 may include a silicon oxide layer, a silicon nitride layer, or a combination thereof. In particular embodiments, the via hole insulating layer 27 may be a non-porous silicon oxide layer. In some embodiments, the via hole insulating layer 27 may be formed using an O₃-TEOS (ozone-tetra-ethyl-ortho-silicate) CVD (chemical vapor deposition) process.

Referring to FIG. 8, a through silicon via electrode 30 may be formed on the via hole insulating layer 27 and in the via hole 21. The through silicon via electrode 30 may include a barrier layer 32 and a conductive layer 34 on the barrier layer 32. A process for forming the through silicon via electrode 30 will be described in detail hereinafter (also with reference to FIG. 2).

The barrier layer 32 may be formed on a surface of the via hole insulating layer 27. In particular, the barrier layer 32 may be conformably formed along an inner surface of the via hole insulating layer 27 in the via hole 21. The barrier layer 24 may be formed to include a titanium layer, a titanium nitride layer, a tantalum layer, a tantalum nitride layer, a ruthenium layer, a cobalt layer, a manganese layer, a tungsten nitride layer, a nickel layer, a nickel boride layer, and/or a double layer of a titanium layer and a titanium nitride layer. The barrier layer 32 may be formed using a sputtering method. The barrier layer 32 may be formed at a temperature of about 375° C. The barrier layer 32 can reduce or prevent metal atoms in a conductive layer 34 (for forming a through silicon via electrode as described hereinafter) from diffusing into the substrate 10.

The conductive layer 34 may be formed to fill the via hole 21. The conductive layer 34 may also be formed to extend onto the barrier layer 32 located outside the via hole 21. The conductive layer 34 may be formed in the via hole 21 using an electro plating method, an electroless plating method, and/or a selective deposition method. The electro plating method may include forming a seed layer on the barrier layer 24 and plating a conductive material on the seed layer. The electro plating method for forming the conductive layer 34 may be performed at room temperature. The seed layer may be formed using a sputtering method. The conductive layer 34 may be formed of a metal layer. For example, the conductive layer 26 may be formed of a silver layer, a gold layer, a copper layer, an aluminum layer, a tungsten layer, and/or an indium layer.

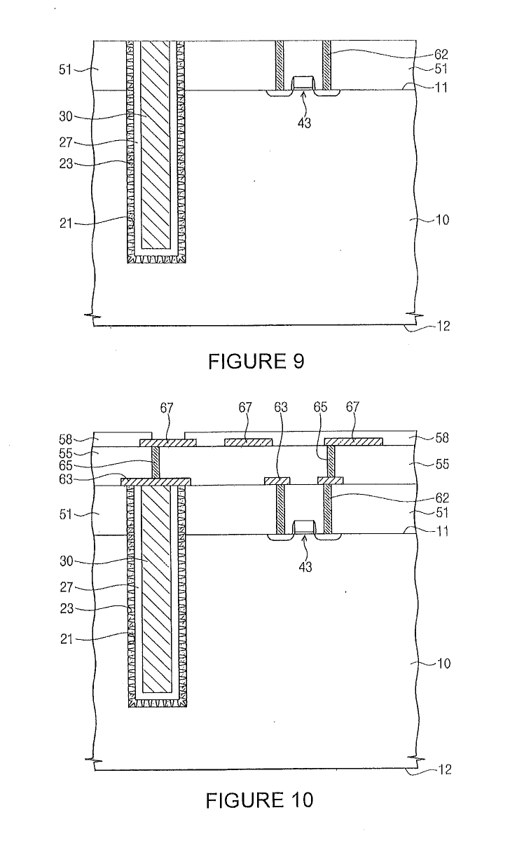

Referring to FIG. 9, the through silicon via electrode 30 on the etch stop layer 53 may be removed using a planarization process. During the planarization process, the porous layer 23 and the via hole insulating layer 27 on the etch stop layer 53 may also be removed. The etch stop layer 53 may be then removed to expose the first interlayer insulating layer 51.

Referring to FIG. 10, first pads 63 may be formed on the first interlayer insulating layer 51. The first pads 63 may be connected to the through silicon via electrode 30 and/or the first contacts 62. A second interlayer insulating layer 55 may be formed on the first interlayer insulating layer 51 and the first pads 63. The second interlayer insulating layer 55 may be formed to include a silicon oxide layer. The second interlayer insulating layer 55 may be formed using a chemical vapor deposition (CVD) process. The second interlayer insulating layer 55 may be formed of a tetra-ethyl-ortho-silicate (TEOS) layer. The second interlayer insulating layer 55 may be formed at a temperature of about 400° C.

Second contacts 65 may be formed in the second interlayer insulating layer 55. The second contacts 65 may be formed by patterning the second interlayer insulating layer 55 to form openings that expose the first pads 63 and by filling the openings with an aluminum layer and/or a tungsten layer.

Second pads 67 may be formed on the second interlayer insulating layer 55. At least one of the second pads 67 may be connected to at least one of the second contacts 65. A first passivation layer 58 may be formed to cover the second interlayer insulating layer 55 and to expose at least one of the second pads 67. The first passivation layer 58 protects an integrated circuit including the semiconductor element 43 from an external environment. The first passivation layer 58 may be formed of a silicon oxide layer, a silicon nitride layer or a combination thereof. The pads 63 and 67 may be formed of an aluminum layer or a tungsten layer.

Referring again to FIG. 1, a polishing process may be then applied to the second surface 12 of the substrate 10 after formation of the first passivation layer 58. As a result of the polishing process, the through silicon via electrode 30 may be exposed at the polished second surface 12. Hereinafter, the polishing process will be described in greater detail.

First, a carrier substrate may be attached to a top surface of the first passivation layer 58 opposite to the second interlayer insulating layer 55 using an adhesion layer. The carrier substrate may alleviate a mechanical stress applied to the substrate 10 while the polishing process is applied to the second surface 12. Further, the carrier substrate may support the substrate that will be thinned after the polishing process, thereby reducing or preventing the thinned substrate from being warped. The carrier substrate may include a glass substrate, a quartz substrate, and/or a resin substrate. The adhesion layer may include an ultraviolet reactive adhesive and/or a thermoplastic adhesive. After the carrier substrate is attached to the first passivation layer 58, the second surface 12 of the substrate 10 may be polished to expose the via hole insulation layer 27. The polishing process, for example, may be performed using at least one of a chemical mechanical polishing (CMP) technique, an etch-back technique, and a spin etching technique.

An etching process may be applied to the second surface 12 of the polished substrate 10 so that the through silicon via electrode 30 surrounded by the via hole insulating layer 27 relatively protrudes from the second surface 12 of the etched substrate 10. The etching process may selectively etch the substrate 10, and the selective etching process may be performed using a wet etching process or a dry etching process that exhibits a relatively high etch selectivity with respect to the porous layer 23 and the via hole insulating layer 27. For example, when the porous layer 23 and the via hole insulating layer 27 are formed of a silicon oxide layer, the substrate 10 may be selectively etched using a sulfur hexafluoride (SF₆) gas.

A second passivation layer 59 may be formed on the second surface 12 of the polished and etched substrate 10. The second passivation layer 59, the porous layer 23 and the via hole insulating layer 27 may be etched to expose the through silicon via electrode 30. A third pad 69 may be formed on the second passivation layer 59. The third pad 69 may be electrically connected to the through silicon via electrode 30. The second passivation layer 59 may be formed of a silicon oxide layer, a silicon nitride layer, or a combination thereof. The third pad 69 may be formed of a copper layer.

According to the embodiments described above, the first mask layer 24 is etched using the porous second mask layer 26 as an etch mask to form a plurality of pores in the first mask layer 24, and the buffer layer 22 is etched using the first mask layer 24 having the pores as an etch mask to form the porous layer 23 having a plurality of pores therein. However, it will be understood that the inventive concept is not limited to the above embodiments. For example, the first mask layer 24 may not be used in formation of the porous layer 23 in some embodiments. That is, the buffer layer 22 may be directly etched using the porous second mask layer 26 as an etch mask without the first mask layer 24. In this case, the porous second mask layer 26 may be formed of a material layer having an etch selectivity with respect to the buffer layer 22. The porous second mask layer 26 may be formed using a diblock copolymer technique. That is, the buffer layer 22 may be etched using a block layer having a plurality of holes as an etch mask, thereby forming the porous layer 23 having a plurality pores therein. The etching process of the buffer layer 22 may be performed in a substantially similar manner as described with reference to FIGS. 5 and 6. In this case, the buffer layer 22 may be etched using an etching recipe that exhibits a property such that the porous second mask layer 26 etched less than the buffer layer 22.

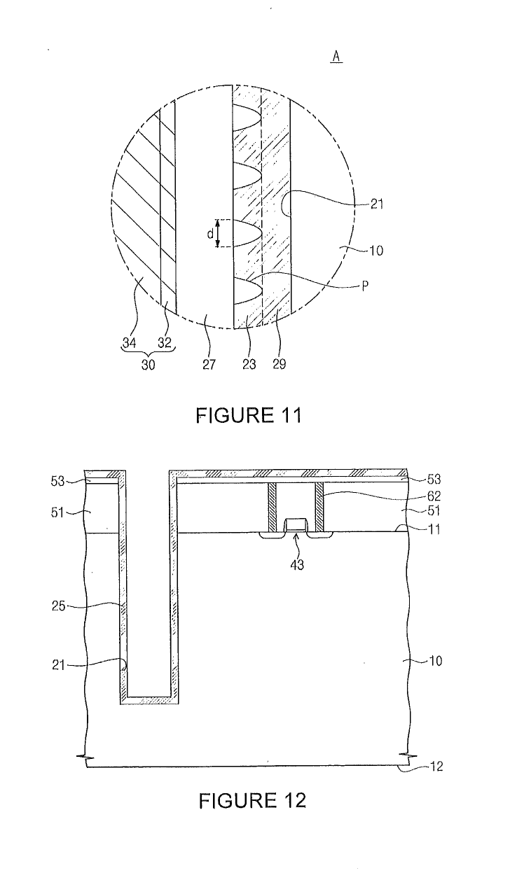

FIG. 11 is a cross sectional view illustrating another example of a microelectronic semiconductor device 101 according to some embodiments of the inventive concept. For the purpose of simplification in explanation, the following description will focus on differences between the semiconductor device illustrated in FIGS. 1 and 2 and the semiconductor device according to the present embodiment of FIG. 11.

Referring to FIG. 11, a non-porous second via hole insulating layer 29 may be additionally provided between the porous layer 23 and the substrate 10. The second via hole insulating layer 29 may include a silicon oxide layer, a silicon nitride layer, or a combination thereof. In particular embodiments, the second via hole insulating layer 29 may be a silicon oxide layer. Meanwhile, in the processes described with reference to FIGS. 5 and 6, the buffer layer (22 of FIG. 5) may be partially etched so that the pores in the buffer layer do not expose the sidewall of the via hole 21. In this case, the second via hole insulating layer 29 may correspond to a remaining portion of the buffer layer 22, which exists between the sidewall of the via hole 21 and the pores in the buffer layer 22. In other words, in some embodiments, the second via hole insulating layer 29 may be a portion of the porous layer 23 through which the pores P do not extend. The porous layer 23 therefore has a dielectric constant that is less than the non-porous second via hole insulating layer 29.

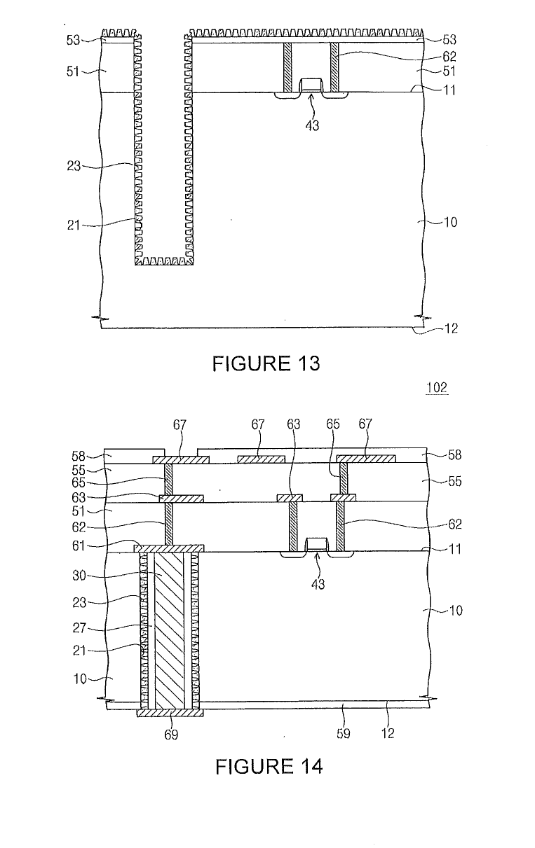

Another example method of fabricating the semiconductor device 101 will be described hereinafter. FIGS. 12 and 13 are cross sectional views illustrating another example method of forming the semiconductor device 101 according to some embodiment of the inventive concept. For the purpose of simplification in explanation, the following description will focus on differences between the embodiments illustrated in FIGS. 3 to 10 and the present embodiment of FIGS. 12 and 13.

Referring to FIG. 12, a preliminary porous low-k dielectric layer, such as a preliminary porous silicon oxide layer 25, may be formed on the substrate including the via hole 21 described with reference to FIG. 3. The preliminary porous silicon oxide layer 25 may be a silicon oxide layer containing carbon. The carbon and the silicon in the preliminary porous silicon oxide layer 25 may be combined with each other to transform a SiO₂ network structure of the preliminary porous silicon oxide layer 25 into a cage-like structure having a less dense structure than the preliminary porous silicon oxide layer 25. The silicon oxide layer having the cage-like structure may correspond to a SiCOH layer. Trimethylsilane ((CH3)3—Si—H) 3MS, tetramethylsilane ((CH3)4—Si) 4MS, or vinyltrimethylsilane (CH2═CH—Si(CH3)3) VTMS may be used as a precursor of the SiCOH layer. The silicon oxide layer containing carbon may be deposited using a plasma enhanced chemical vapor deposition (PECVD) process. The silicon oxide layer containing carbon may be transformed into the porous layer 23, i.e., the porous SiCOH (p-SiCOH) layer by a heating process.

In particular, as shown in FIG. 13, the silicon oxide layer containing carbon may be transformed into the porous layer 23, i.e., a porous SiCOH (p-SiCOH) layer by a heating process. The porous layer 23 may have a plurality of pores therein. The pores may have a size (e.g., a diameter) of about several ten nanometers to several hundred nanometers. That is, in contrast to previously described embodiments, the porous SiCOH (p-SiCOH) layer may be formed directly using the preliminary porous silicon oxide layer 25 containing carbon (which was used as the second mask layer 26 in the previously described embodiments), without using the buffer layer 22 and the first mask layer 24 illustrated in FIGS.4 and 5 of the previous embodiment.

Subsequently, the semiconductor device 101 according to some embodiments of the inventive concept may be formed using processes which are similar to the methods described with reference to FIGS. 7 to 10. The porous layer 23 of the semiconductor device 101 formed using these methods may correspond to a porous low-k dielectric layer. The porous low-k dielectric layer may be a porous SiCOH layer.

A semiconductor device 102 according to another embodiment of the inventive concept will be described hereinafter. FIG. 14 is a cross sectional view illustrating the semiconductor device 102 according to another embodiment of the inventive concept. For the purpose of simplification in explanation, the following description will focus on differences between the embodiment illustrated in FIGS. 1 and 2 and the present embodiment of FIG. 14.

Referring to FIG. 14, the via hole 21 of the semiconductor device 102 may not penetrate or extend into the first interlayer insulating layer 51 in some embodiments. That is, an upper end of the via hole 21 may be substantially coplanar with the first surface 11 of the substrate 10. As such, FIG. 14 illustrates a via-first structure.

An upper surface of the through silicon via electrode 30 may contact a bottom surface of the first interlayer insulating layer 51, which is adjacent to the first surface 11 of the substrate 10. The through silicon via electrode 30 may include a doped polysilicon. Additionally or alternatively, the through silicon via electrode 30 may include the barrier layer and the conductive layer described with reference to FIGS. 1 and 2. In addition, the via hole insulating layer 27 between the through silicon via electrode 30 and the porous layer 23 may be omitted in some embodiments.

A first pad 61 may be disposed on the first surface 11 of the substrate 10 and may be connected to the through silicon via electrode 30. The first interlayer insulating layer 51 may be disposed on the first surface 11 of the substrate 10, the first pad 61 and the semiconductor element 43. Thus, the via hole 21 may extend from the first surface 11 of the substrate 10, that is, the bottom surface of the first interlayer insulating layer 51 toward a bulk region of the substrate 10. The first interlayer insulating layer 51 may include a silicon oxide layer. Second pads 63 may be disposed on the first interlayer insulating layer 51. Each of the second pads 63 may be connected to the source/drain region of the semiconductor element 43 or the first pad 61 through one of first contacts 62 formed in the first interlayer insulating layer 51. A second interlayer insulating layer 55 may be formed to cover the second pads 63 and the first interlayer insulating layer 51. The second interlayer insulating layer 55 may include a silicon oxide layer. Third pads 67 may be formed on the second interlayer insulating layer 55. At least one of the third pads 67 may be connected to one of the second pads 63 through one of second contacts 65 formed in the second interlayer insulating layer 55.

A first passivation layer 58 may be disposed to cover the second interlayer insulating layer 55 and to expose at least one of the third pads 67. The first passivation layer 58 may protect an integrated circuit including the semiconductor element 43 from an external environment.

A second passivation layer 59 may be formed on the second surface 12 of the substrate 10 opposite to the first surface 11. The second passivation layer 59, the porous layer 23 and the via hole insulating layer 27 on a bottom surface of the through silicon via electrode 30 may be removed using a etching process to expose the bottom surface of the through silicon via electrode 30. A fourth pad 69 may be formed on the second passivation layer 59, and the fourth pad 69 may be connected to the through silicon via electrode 30. The second passivation layer 59 may be formed of a silicon oxide layer, a silicon nitride layer, or a combination thereof. The fourth pad 69 may be formed of a copper layer in some embodiments.

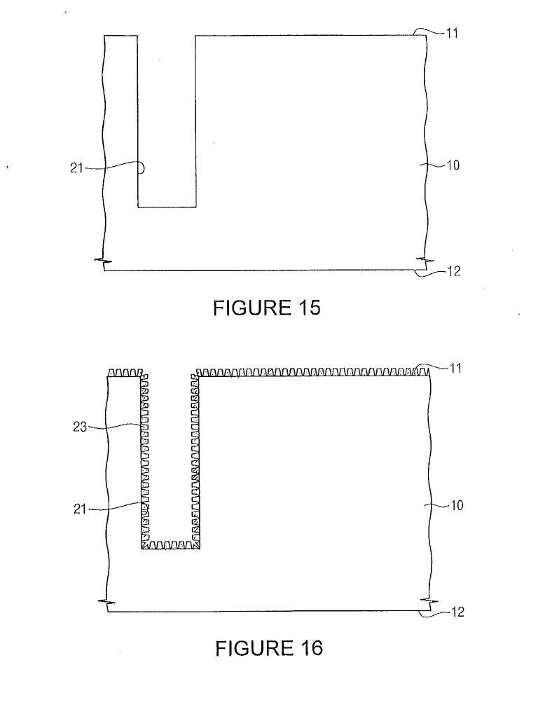

A method of forming the semiconductor device 102 illustrated in FIG. 14 will be described hereinafter. FIGS. 15 to 19 are cross sectional views illustrating a method of forming the semiconductor device 102 according to another embodiment of the inventive concept. For the purpose of simplification in explanation, the following description will focus on differences between the previously described embodiments and the present embodiment of FIGS. 15 to 19.

Referring to FIG. 15, a substrate 10 may be provided. The substrate 10 may include a first surface 11 and a second surface 12 opposite to the first surface 11. The substrate 10 may be doped with P-type impurities.

The substrate 10 may be etched to form a via hole 21. The via hole 21 may extend from the first surface 11 of the substrate 10 toward the second surface 12 of the substrate 10, but may not extend completely through the substrate 10. The substrate 10 may be etched using a drilling process, a Bosch etching process, or a steady state etching process.

Referring to FIG. 16, a porous layer 23 may be formed in the via hole 21 using methods similar to any of the processes of the previously described embodiments.

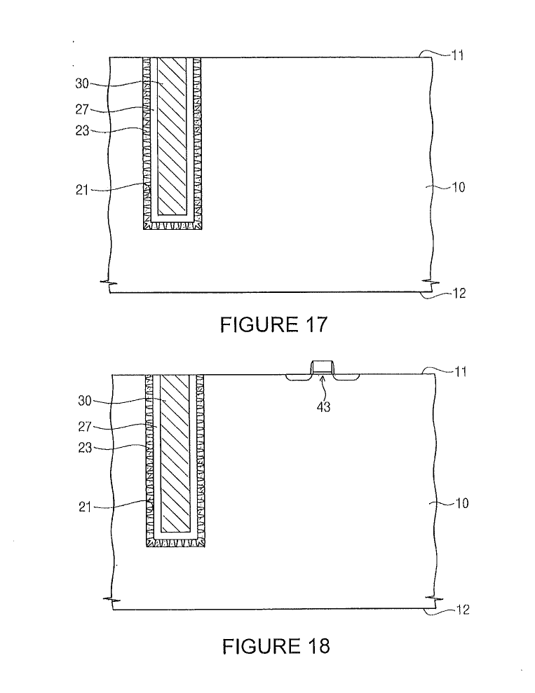

Referring to FIG. 17, a through silicon via electrode 30 may be formed on the porous layer 23 to fill the via hole 21. The through silicon via electrode 30 may be formed using methods similar to any of the processes described with reference to FIGS. 7 to 9. The through silicon via electrode 30 may include a doped polysilicon layer. Additionally or alternatively, the through silicon via electrode 30 may include the barrier layer and the conductive layer of the previously described embodiments. Further, a via hole insulating layer 27 may be additionally formed between the porous layer 23 and the through silicon via electrode 30. The via hole insulating layer 27 may include a silicon oxide layer, a silicon nitride layer, or a combination thereof. For example, the via hole insulating layer 27 may be a non-porous silicon oxide layer. Portions of the through silicon via electrode 30 on the first surface 11 of the substrate 10 may be selectively removed. Portions of the via hole insulating layer 27 on the first surface 11 of the substrate 10 may also removed during removal of the through silicon via electrode 30 on the first surface 11.

Referring to FIG. 18, a semiconductor element 43 or other microelectronic component may be formed on the first surface 11 and in the substrate 10 under the first surface 11. The semiconductor element 43 may include a transistor. For example, the semiconductor element 43 may include an NMOS transistor, a PMOS transistor, or a bipolar transistor. The semiconductor element 43 may be formed prior to formation of the via hole 21 described with reference to FIG. 15.

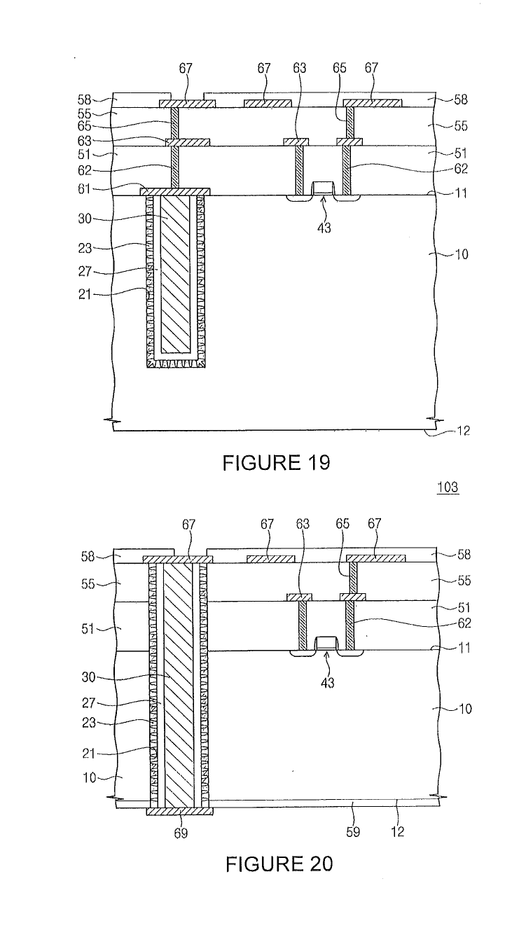

Referring to FIG. 19, a first pad 61 may be formed on the first surface 11 of the substrate 10 and may be connected to the through silicon via electrode 30. A first interlayer insulating layer 51 may be formed on the first pads 61, the semiconductor element 43 and the first surface 11 of the substrate 10. First contacts 62 may be formed in the first interlayer insulating layer 51, and the first contacts 62 may be connected to the source/drain regions of the semiconductor element 43 and/or the first pad 61. Second pads 63 may be formed on the first interlayer insulating layer 51, and the second pads 63 may be connected to the first contacts 62.

A second interlayer insulating layer 55 may be formed on the first interlayer insulating layer 51 and the second pads 63. Second contacts 65 may be formed in the second interlayer insulating layer 55, and at least one of the second contacts 65 may be connected to one of the second pads 63. Third pads 67 may be formed on the second interlayer insulating layer 55, and at least one of the third pads 67 may be connected to one of the second contacts 65.

A first passivation layer 58 may be formed to cover the second interlayer insulating layer 55 and to expose at least one of the third pads 67. The first passivation layer 58 may protect an integrated circuit including the semiconductor element 43 from an external environment. The first passivation layer 58 may be formed of a silicon oxide layer, a silicon nitride layer, or a combination thereof. The pads 61, 63 and 67 may be formed of an aluminum layer and/or a copper layer. The contacts 62 and 65 may be formed of an aluminum layer and/or a tungsten layer.

Referring again to FIG. 14, a polishing process may be then applied to the second surface 12 of the substrate 10 after formation of the first passivation layer 58. As a result of the polishing process, the substrate 10 may be thinned and the through silicon via electrode 30 may be exposed at the polished second surface 12. The polishing process may be similar to that of the previously described embodiments. A second passivation layer 59 may be formed on the second surface 12 of the polished substrate 10. The second passivation layer 59, the porous layer 23 and the via hole insulating layer 27 may be etched to expose the through silicon via electrode 30. A fourth pad 69 may be formed on the second passivation layer 59. The fourth pad 69 may be electrically connected to the through silicon via electrode 30. The second passivation layer 59 may be formed of a silicon oxide layer, a silicon nitride layer, or a combination thereof. The fourth pad 69 may be formed of a copper layer.

FIG. 20 is a cross sectional view illustrating a semiconductor device 103 according to still another embodiment of the inventive concept. For the purpose of simplification in explanation, the following description will focus on differences between the previously described embodiments and the present embodiment of FIG. 20.

Referring to FIG. 20, a first interlayer insulating layer 51 may be disposed on the first surface 11 of the substrate 10, thereby covering the semiconductor element 43. The first interlayer insulating layer 51 may include a silicon oxide layer. First contacts 62 may penetrate the first interlayer insulating layer 51, and the first contacts 62 may be connected to impurity regions of the semiconductor element 43, for example, source/drain regions of a MOS transistor. First pads 63 may be formed on the first interlayer insulating layer 51. The first pads 63 may be connected to the first contacts 62. A second interlayer insulating layer 55 may be formed to cover the first interlayer insulating layer 51 and the first pads 63. The second interlayer insulating layer 55 may include a silicon oxide layer.

A via hole 21 of the semiconductor device 103 may penetrate and extend into the first and second interlayer insulating layers 51 and 55. That is, the via hole 21 may extend from a top surface of the second interlayer insulating layer 55 toward the substrate 10.

A through silicon via electrode 30 may fill the via hole 21. The through silicon via electrode 30 may be exposed at a top surface of the second interlayer insulating layer 55. That is, the through silicon via electrode 30 may extend toward the top surface of the second interlayer insulating layer 55 opposite to the first interlayer insulating layer 51. A porous layer 23 and a via hole insulating layer 27 may be disposed between a sidewall of the via hole 21 and the through silicon via electrode 30. The porous layer 23 may have a plurality of pores therein. The pores in the porous layer 23 may extend in a direction which is substantially perpendicular to the sidewall of the via hole 21. The pores may extend completely through the porous layer 23 to expose the sidewall of the via hole 21. The density of the pores in the porous layer 23 may be gradually reduced from the first surface 11 of the substrate 10 toward the second surface 12 of the substrate 10. The pores may have a size (e.g., a diameter or other dimension) of about several ten nanometers to several hundred nanometers. The porous layer 23 may include a silicon oxide layer, a silicon nitride layer, or a combination thereof. For example, the porous layer 23 may be a porous silicon oxide layer in some embodiments. The via hole insulating layer 27 may include a silicon oxide layer, a silicon nitride layer, or a combination thereof. The via hole insulating layer 27 may be a non-porous silicon oxide layer.

Second pads 67 may be formed on the second interlayer insulating layer 55. One of the second pads 67 may be connected to the through silicon via electrode 30. A first passivation layer 58 may be formed to cover the second interlayer insulating layer 55 and to expose at least one of the second pads 67. The first passivation layer 58 may protect an integrated circuit including the semiconductor element 43 from an external environment.

A second passivation layer 59 may be formed on the second surface 12 of the substrate 10. A third pad 69 may be formed on the second passivation layer 59. The third pad 69 may be connected to the through silicon via electrode 30. The second passivation layer 59 may be formed of a silicon oxide layer, a silicon nitride layer or a combination thereof. The third pad 69 may be formed of a copper layer.

A method of forming the semiconductor device 103 according to the embodiment illustrated in FIG. 20 may be similar to the method of forming the semiconductor device 101 described above. For the purpose of simplification in explanation, the following description will focus on differences between the method of forming the semiconductor device 101 and a method of forming the semiconductor device 103 according to the present embodiment.

Referring again to FIG. 20, a process for forming the via hole 21 of the semiconductor device 103 may be performed after formation of the second interlayer insulating layer 55, in contrast to the previously described embodiments. As such, FIG. 20 illustrates a via-last structure.

Subsequently, second pads 67 may be formed on the second interlayer insulating layer 55. A first passivation layer 58 may be formed to cover the second interlayer insulating layer 55 and to expose at least one of the second pads 67. The first passivation layer 58 may protect an integrated circuit including the semiconductor element 43 from an external environment. The first passivation layer 58 may be formed of a silicon oxide layer, a silicon nitride layer, or a combination thereof.

A second passivation layer 59 may be formed on the second surface 12 of the substrate 10. A third pad 69 may be formed on the second passivation layer 59. The third pad 69 may be connected to the through silicon via electrode 30. The second passivation layer 59 may be formed of a silicon oxide layer, a silicon nitride layer, or a combination thereof. The third pad 69 may be formed of a copper layer.

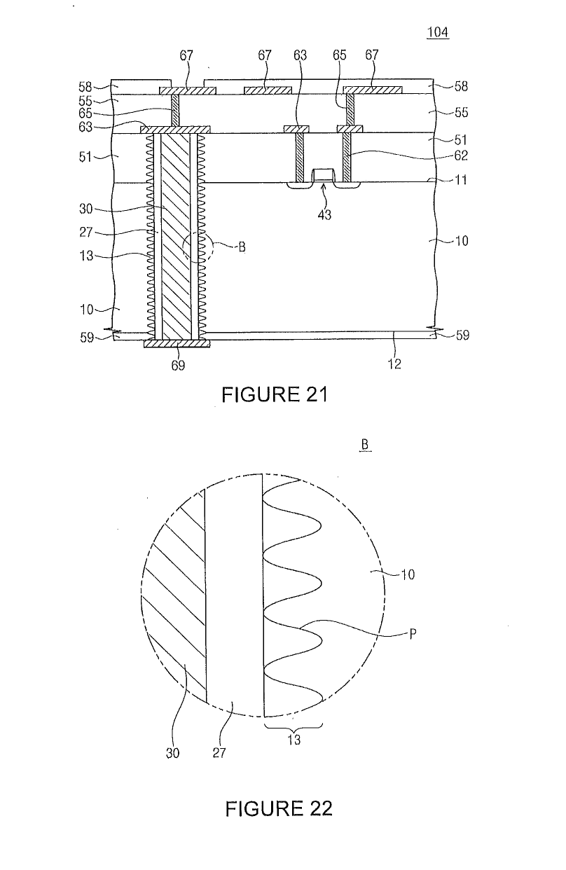

A semiconductor device 104 according to yet another embodiment of the inventive concept will be described hereinafter. FIG. 21 is a cross sectional view illustrating the semiconductor device 104 according to yet another embodiment of the inventive concept, and FIG. 22 is an enlarged view of a portion ‘B’ of FIG. 21. For the purpose of simplification in explanation, the following description will focus on differences between the semiconductor devices illustrated in the previously described embodiments and the semiconductor device 104 according to the present embodiment of FIGS. 21 and 22.

Referring to FIGS. 21 and 22, the semiconductor device 104 may include a substrate 10 having a first surface 11 and a second surface 12 opposite to the first surface 11. The substrate 10 may be doped with P-type impurities.

A semiconductor element 43 or other microelectronic component may be formed on the first surface 11 and in the substrate 10 under the first surface 11. The semiconductor element 43 may be a transistor. For example, the semiconductor element 43 may be an NMOS transistor, a PMOS transistor or a bipolar transistor. A first interlayer insulating layer 51 may be formed on the first surface 11 of the substrate 10 and on the semiconductor element 43. The first interlayer insulating layer 51 may include a silicon oxide layer.

A via hole 21 may penetrate and extend through the first interlayer insulating layer 51 and the substrate 10. The via hole 21 may extend from the first interlayer insulating layer 51 on the first surface 11 toward the second surface 12 of the substrate 10. The via hole 21 may have a depth of about 50 μm.

A through silicon via electrode 30 may fill the via hole 21. The through silicon via electrode 30 may be exposed at the second surface 12. A porous layer 13 and a via hole insulating layer 27 may be disposed between a sidewall of the via hole 21 and the through silicon via electrode 30. The porous layer 13 may be a single crystalline silicon layer having a plurality of pores P. In particular embodiments, the porous layer 13 may be a portion of the substrate 10 that defines the sidewalls of the via hole 21. The pores P may extend from the sidewall of the via hole 21 into the substrate 10. The pores P may extend in a direction which is substantially perpendicular to the sidewalls of the via hole 21. The density of the pores P may be gradually reduced from the first surface 11 of the substrate 10 toward the second surface 12 of the substrate 10. The pores P may have a size (e.g., a diameter or other dimension) of about several ten nanometers to several hundred nanometers. The via hole insulating layer 27 may include a silicon oxide layer, a silicon nitride layer, or a combination thereof. In particular embodiments, the via hole insulating layer 27 may be a non-porous silicon oxide layer.

Elements other than the aforementioned elements may have configurations which are similar to the corresponding elements illustrated in FIG. 1.

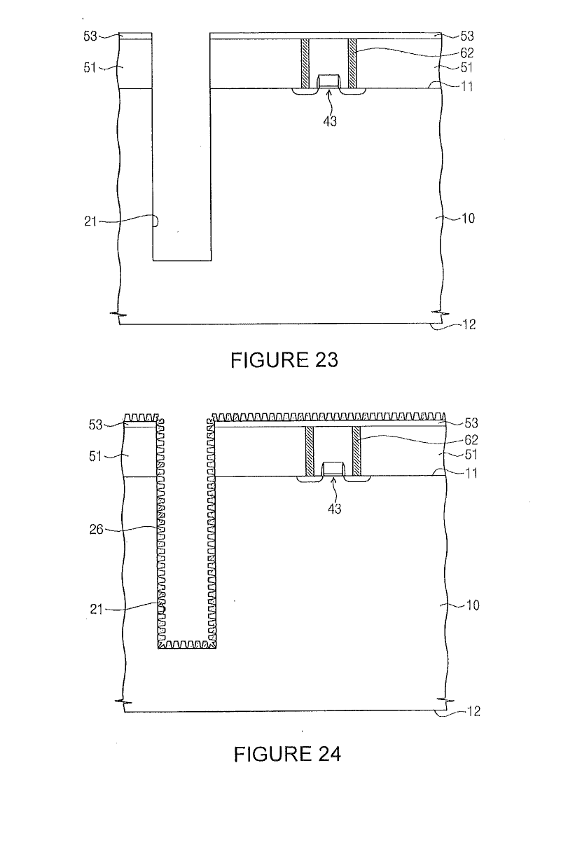

A method of forming the semiconductor device 104 according to yet another embodiment of the inventive concept will be described hereinafter. FIGS. 23 to 26 are cross sectional views illustrating a method of forming a semiconductor device according to still another embodiment of the inventive concept.

Referring to FIG. 23, a substrate 10 may be provided. The substrate 10 may include a first surface 11 and a second surface 12 opposite to the first surface 11. The substrate 10 may be doped with impurities, for example, P-type impurities.

A microelectronic component or semiconductor element 43 may be formed on the first surface 11 and/or in the substrate 10 under the first surface 11. The semiconductor element 43 may be a transistor. For example, the semiconductor element 43 may be an NMOS transistor, a PMOS transistor or a bipolar transistor. FIG. 23 illustrates a single semiconductor element 43. However, the number of semiconductor elements 43 is not limited to one. That is, the number of semiconductor elements 43 may be two or more in some embodiments.

A first interlayer insulating layer 51 may be formed on the first surface 11 of the substrate and on the semiconductor element 43. The first interlayer insulating layer 51 may include a silicon oxide layer. First contacts 62 may be formed to penetrate the first interlayer insulating layer 51. The first contacts 62 may be formed of a tungsten material. The first contacts 62 may be connected to impurity regions of the semiconductor element 43, for example, source/drain regions of a MOS transistor.

An etch stop layer 53 may be formed on the first interlayer insulating layer 51. The etch stop layer 53 may include a silicon nitride layer. The etch stop layer 53 may be used as a mask pattern. The first interlayer insulating layer 51 and the substrate 10 may be etched using the etch stop layer 53 as an etch mask, thereby forming a via hole 21. The via hole 21 may be formed using a drilling process, a Bosch etching process, or a steady state etching process. The via hole 21 may penetrate the etch stop layer 53 and the first interlayer insulating layer 51, and the via hole 21 may extend from the first surface 11 toward the second surface 12. The via hole 21 may be formed not to penetrate completely through the substrate 10. In some embodiments, the via hole 21 may be formed to have a depth of about 50 μm or more.

Referring to FIG. 24, a porous mask layer 26 may be formed on the substrate including the via hole 21. The porous mask layer 26 may be conformally formed on sidewalls and a bottom surface of the via hole 21. The porous layer 26 may have a plurality of pores therein and may have an etch selectivity with respect to the substrate 10. The pores in the porous mask layer 26 may have a size (e.g., a diameter or other dimension) of about several ten nanometers to about several hundred nanometers. The porous mask layer 26 may be formed in a manner similar to that described in any of the embodiments previously discussed herein.

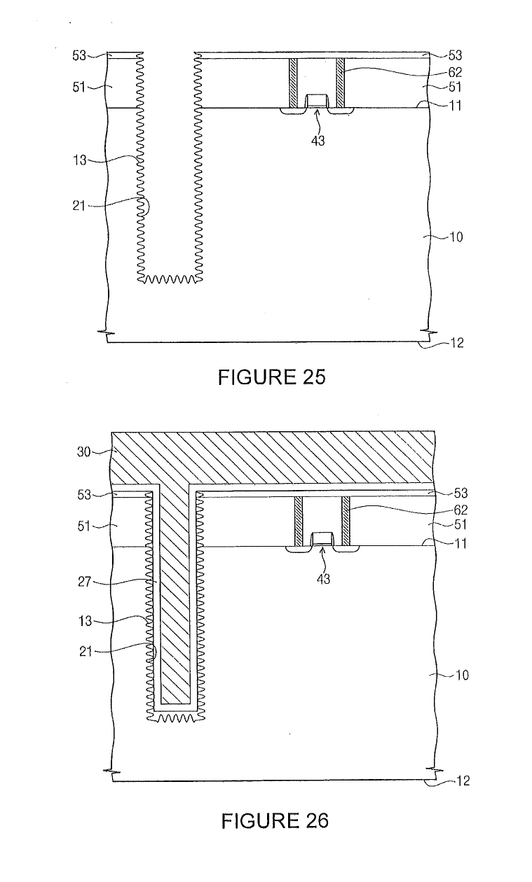

Referring to FIG. 25, the substrate 10 may be etched using the porous mask layer 26 as an etch mask, thereby forming a plurality of pores in the substrate 10 at the sidewalls and the bottom surface of the via hole 21. While the pores are formed, the etch stop layer 53 may reduce or prevent the first surface 11 of the substrate 10 from being etched. The pores may be formed to extend in a direction which is substantially perpendicular to the sidewalls of the via hole 21. Consequently, a porous single crystalline silicon layer 13 may be formed in the sidewall and the bottom surface of the via hole 21 (see FIG. 22).

Referring to FIG. 26, a via hole insulating layer 27 may be formed on the substrate including the porous single crystalline silicon layer 13. The via hole insulating layer 27 may aid in a formation process of a conductive layer (e.g., a copper layer) to be used as a through silicon via electrode in a subsequent process. The via hole insulating layer 27 may include a silicon oxide layer, a silicon nitride layer, or a combination thereof. The via hole insulating layer 27 may be a non-porous silicon oxide layer. In some embodiments, the via hole insulating layer 27 may be formed using an O₃-TEOS CVD process. The via hole insulating layer 27 may have step coverage properties so as not to extend into the pores in the porous layer 13.

A through silicon via electrode 30 may be formed on the via hole insulating layer 27 to fill the via hole 21. The through silicon via electrode 30 may include a barrier layer 32 and a conductive layer 34 on the barrier layer, as illustrated in FIG. 2. The formation process of the through silicon via electrode 30 may be similar to the corresponding processes described in the previous embodiments.

Subsequently, the semiconductor device 104 illustrated in FIG. 21 may be completed using similar processes as those discussed above with reference to the previous embodiments.

As described above, in some embodiments, the interlayer insulating layers, the passivation layers and/or the interconnection lines may be formed after formation of the through silicon via electrode 30. The processes after formation of the through silicon via electrode 30 may be performed at a temperature greater than room temperature. In addition, the semiconductor device including the through silicon via electrode 30 may generate heat during operation of the semiconductor device. As the through silicon via electrode 30 may be formed of a metal layer, the through silicon via electrode 30 may expand or contract according to variations in the thermal environment. As the thermal expansion coefficient of the through silicon via electrode 30 may be different from that of a material (for example, a silicon material) constituting the substrate 10, the substrate 10 may be subjected to a thermal stress due to the processes performed after formation of the through silicon via electrode 30 and/or due to the operation of the semiconductor device. This thermal stress may affect characteristics the semiconductor element 43, for example, a transistor. However, the porous layer in accordance with embodiments of the inventive concept described herein may alleviate the thermal stress that affects the characteristics the semiconductor element 43, which may thereby improve operating characteristics and/or reliability.

Moreover, the porous layer in accordance with embodiments of the inventive concept described herein may have a dielectric constant which is less than that of a silicon oxide layer in some embodiments. Thus, the parasitic capacitance between the through silicon via electrode and wirings (and/or substrate) adjacent thereto may be reduced to improve the performance of the semiconductor device.

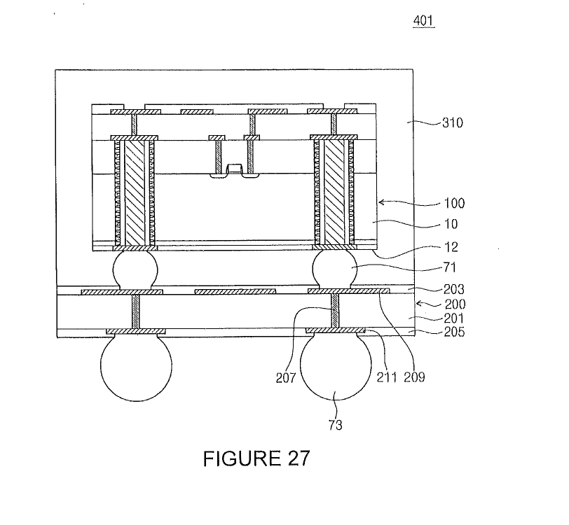

FIGS. 27 to 29 illustrate examples of semiconductor packages according to embodiments of the inventive concept.

Referring to FIG. 27, an example 401 of a semiconductor package according to the embodiments of the inventive concept may include a package or module substrate 200 and a microelectronic semiconductor device 100 mounted on the package substrate 200. The package substrate 200 may be a printed circuit board (PCB). The package substrate 200 may include an insulation substrate 201, a package substrate through via 207 penetrating the insulation substrate 201, conductive patterns 209 and 211 disposed on the top and bottom surfaces of the insulation substrate 201, and package substrate insulation layers 203 and 205 covering the conductive patterns 209 and 211. The semiconductor device 100 may correspond to any of the semiconductor devices described above with reference to FIGS. 1 to 26.

The semiconductor device 100 may be mounted on the package substrate 200. For example, the package substrate 200 may be disposed on the second surface of 12 of the substrate 10 opposite the first surface 11. That is, the semiconductor device 100 may be electrically connected to the package substrate 200 through first bumps 71. Second bumps 73 may be attached to a bottom surface of the package substrate 200 opposite the first bumps 71. The bumps 71 and 73 may correspond to solder balls, conductive bumps, conductive spacers, pin grid arrays, or a combination thereof. The semiconductor package 401 may further include a mold layer 310 surrounding or covering the semiconductor device 100. The mold layer 310 may include an epoxy molding compound material.

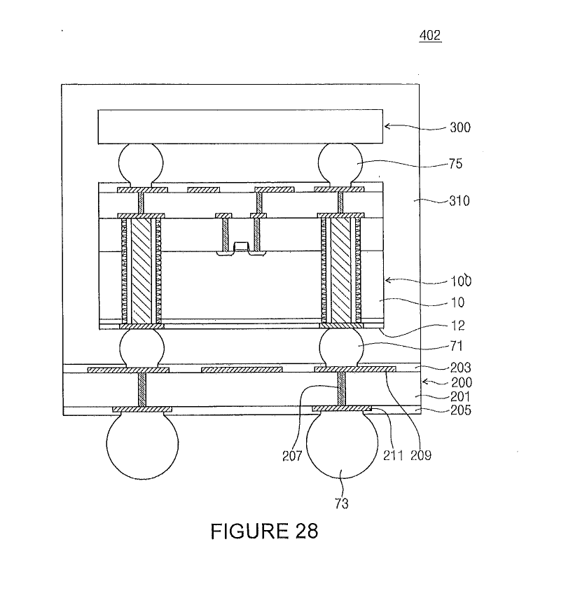

Referring to FIG. 28, another example 402 of a semiconductor package according to some embodiments of the inventive concept may include a package or module substrate 200 and first and second semiconductor devices 100 and 300 mounted on the package substrate 200. The package substrate 200 may be a printed circuit board (PCB). The package substrate 200 may include an insulation substrate 201, a package substrate through via 207 penetrating the insulation substrate 201, conductive patterns 209 and 211 disposed on the top and bottom surfaces of the insulation substrate 201, and package substrate insulation layers 203 and 205 covering the conductive patterns 209 and 211. The first semiconductor device 100 may correspond to any of the semiconductor devices described above with reference to FIGS. 1 to 26. The second semiconductor device 300 may correspond to a memory chip or a logic chip which is different from the first semiconductor device 100. In some embodiments, the second semiconductor device 300 may not include the through silicon via electrode structures described herein.

The first semiconductor device 100 may be electrically connected to the package substrate 200 through first bumps 71. The second semiconductor device 300 may be mounted on the first semiconductor device 100 opposite the package substrate 200 using a flip chip bonding technique. The second semiconductor device 300 may be electrically connected to the first semiconductor device 100 through third bumps 75. The first semiconductor device 100 may act as an interposer. The number of the third bump 75 may be two or more, and the number of the through silicon via electrodes 30 may also be two or more. A distance between the third bumps 75 may be different from a distance between the through silicon via electrodes 30.

Second bumps 73 may be attached to a bottom surface of the package substrate 200 opposite the first bumps 71. The bumps 71, 73 and 75 may correspond to solder balls, conductive bumps, conductive spacers, pin grid arrays or a combination thereof. The semiconductor package 402 may further include a mold layer 310 surrounding or covering the first and second semiconductor devices 100 and 300. The mold layer 310 may include an epoxy molding compound material.

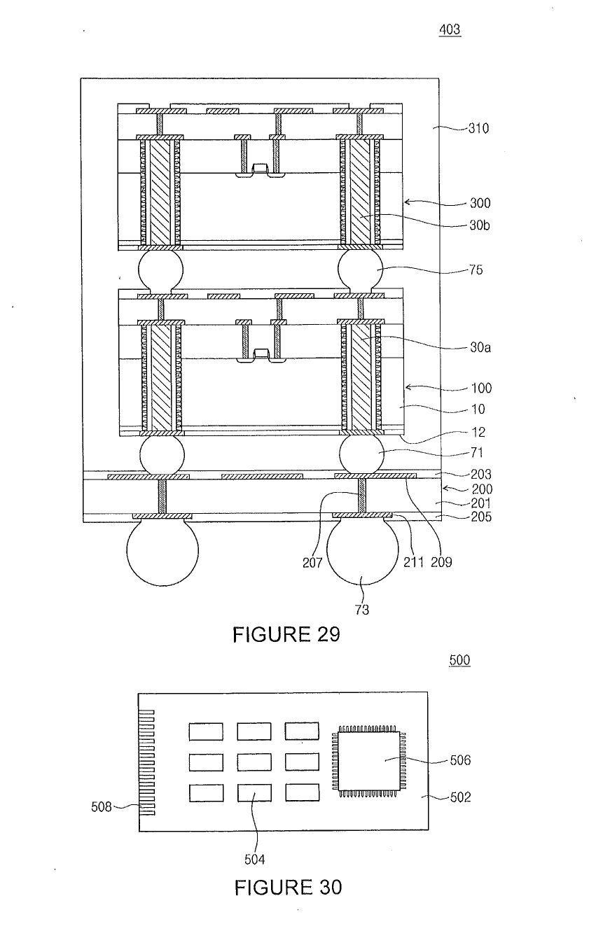

Referring to FIG. 29, still another example 403 of a semiconductor package according to the embodiments of the inventive concept may include a package or module substrate 200 and first and second semiconductor devices 100 and 300 mounted on the package substrate 200. The semiconductor package 403 may be a multi-chip package or module. The first and second semiconductor devices 100 and 300 may have a same type of configuration and a same structure in some embodiments.

The package substrate 200 may be a printed circuit board (PCB). The package substrate 200 may include an insulation substrate 201, a package substrate through via 207 penetrating the insulation substrate 201, conductive patterns 209 and 211 disposed on the top and bottom surfaces of the insulation substrate 201, and package substrate insulation layers 203 and 205 covering the conductive patterns 209 and 211. The first and second semiconductor devices 100 and 300 may have the same structure as any of the semiconductor devices described above with reference to FIGS. 1 to 26.

The first and second semiconductor devices 100 and 300 may include first through silicon via electrodes 30a and second through silicon via electrodes 30b, respectively. The first through silicon via electrodes 30a and the second through silicon via electrodes 30b may be sequentially stacked to overlap with each other in a plan view. The first through silicon via electrodes 30a may be electrically connected to the second through silicon via electrodes 30b through third bumps 75.

The first semiconductor device 100 may be electrically connected to the package substrate 200 through first bumps 71. The first semiconductor device 100 may act as an interposer. Second bumps 73 may be attached to a bottom surface of the package substrate 200 opposite the first bumps 71. The bumps 71, 73 and 75 may correspond to solder balls, conductive bumps, conductive spacers, pin grid arrays or a combination thereof. The semiconductor package 403 may further include a mold layer 310 surrounding or covering the first and second semiconductor devices 100 and 300. The mold layer 310 may include an epoxy molding compound material.

The semiconductor packages according to the above embodiments may be configured to have a structure such that at least one semiconductor device is electrically connected to the package substrate by through silicon via electrodes. However, it will be understood that semiconductor packages according to embodiments of the inventive concept are not limited to the embodiments described above. For example, some of the pads of the semiconductor device may be electrically connected to the package substrate through bonding wires.

FIG. 30 is a plan view illustrating a package module 500 including a semiconductor device according to embodiments of the inventive concept. Referring to FIG. 30, the package module 500 may include a module substrate 502 having terminals 508 configured to be connected to an external device, at least one semiconductor chip 504 mounted on the module substrate 502, and a semiconductor package 506 having a quad flat package (QFP) type configuration. The semiconductor chip 504 and/or the semiconductor package 506 may include a semiconductor device according to the embodiments described above. The package module 500 may be connected to an external electronic device through the terminals 508.

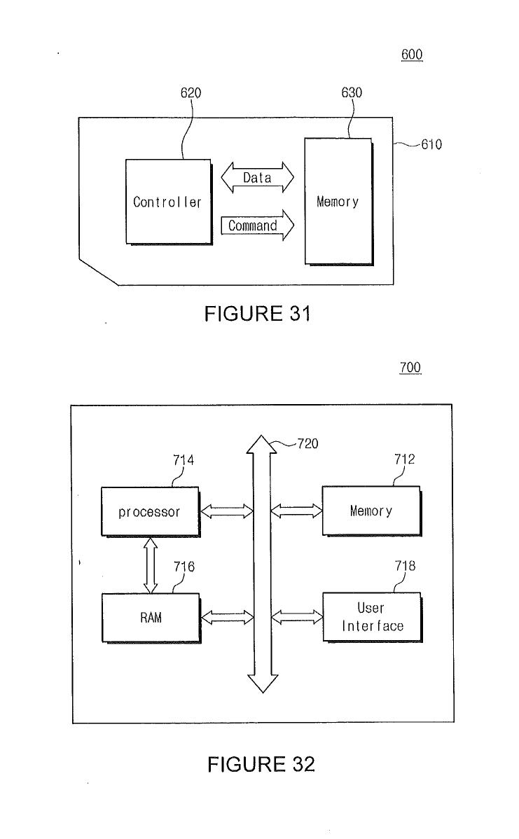

FIG. 31 is a schematic block diagram illustrating a memory card 600 including a semiconductor device according to embodiments of the inventive concept. Referring to FIG. 31, the memory card 600 may include a housing 610 as well as a controller 620 and a memory 630 disposed in the housing 610. The controller 620 and the memory 630 may transmit and receive electrical data to and from each other. For example, the controller 620 and the memory 630 may transmit and receive the electrical data to and from each other according to commands from the controller 620. Thus, the memory card 600 may store the memory 630 with the data or may output the data in the memory 630 to an external device.

The controller 620 and/or the memory 630 may include at least one of the semiconductor devices and the semiconductor packages according to the embodiments of the inventive concept described herein. The memory card 600 may be used as a data storage media of various portable systems. For example, the memory card 600 may be a multi media card (MMC) or a secure digital (SD) card.

FIG. 32 is a schematic block diagram illustrating an electronic system 700 according to embodiments of the inventive concept. Referring to FIG. 32, the electronic system 700 may include at least one of the semiconductor devices and the semiconductor packages according to the embodiments of the inventive concept. The electronic system 700 may be a mobile system or a computer in some embodiments. For example, the electronic system 700 may include a memory system 712, a processor 714, a random access memory (RAM) 716 and a user interface 718. The memory system 712, the processor 714, the random access memory (RAM) 716 and the user interface 718 may communicate with each other through a data bus 720. The processor 714 may execute a program and may control the electronic system 700. The RAM 716 may be used as an operation memory of the processor 714. For example, the processor 714 and the RAM 716 may include one of the semiconductor devices according to the embodiments of the inventive concept and one of the semiconductor packages according to the embodiments of the inventive concept, respectively. The processor 714 and the RAM 716 may be encapsulated in a single package. The user interface 718 may be used to input data from an external device into the electric system 700 or output the data of the electronic system 700 to the external device. The memory system 712 may store a code for operating the processor 714, data processed by the processor 714 or data received from an external device. The memory system 712 may include a controller and a memory. The memory system 712 may have substantially the same configuration as the memory card 600 illustrated in FIG. 31. The electronic system 700 may also be applied to an electronic control system of the various electronic products.

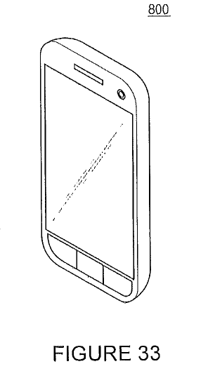

FIG. 33 is a schematic view illustrating a mobile phone 800 to which the electronic system 700 of FIG. 32 can be applied. However, it will be understood that, in other embodiments, the electronic system 700 of FIG. 32 may be applied to portable notebook computers, MP3 players, navigators, solid state disks (SSDs), automobiles, and/or household appliances.

According to the embodiments of the inventive concept discussed above, a parasitic capacitance between a substrate (and/or wiring) and a through silicon via electrode may be reduced by forming a porous layer between the substrate and the through silicon via electrode. Further, the porous layer may alleviate thermal stress of the through silicon via electrode. Thus, the porous layer in accordance with embodiments of the inventive concept may improve electrical characteristics and reliability of microelectronic components formed adjacent to the through silicon via electrode, and may reduce the keep-out zone between such components and the through silicon via electrodes.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

1. A microelectronic device, comprising:
a substrate including a via hole extending therethrough;
a porous layer on sidewalls of the via hole, the porous layer comprising a plurality of pores therein having respective dimensions such that the porous layer is mesoporous or macroporous; and
a conductive via electrode extending through the via hole between the sidewalls thereof.

2. The device of claim 1, wherein the pores of the porous layer have respective dimensions of at least 10 nanometers.

3. The device of claim 1, wherein the pores of the porous layer have respective diameters of about 10 nanometers to about 500 nanometers.

4. The device of claim 3, wherein the pores extend into the porous layer in a direction substantially perpendicular to the sidewalls of the via hole.

5. The device of claim 4, wherein respective diameters of the pores decrease from portions of the porous layer adjacent the conductive via electrode.

6. The device of claim 1, wherein the via hole extends from a first surface of the substrate to a second surface of the substrate opposite the first surface, and wherein the porous layer has a non-uniform pore density that decreases from the first surface towards the second surface.

7. The device of claim 1, wherein the porous layer has a substantially uniform pore density throughout.

8. The device of claim 1, wherein the porous layer comprises a porous insulating layer that surrounds the conductive via electrode and separates the conductive via electrode from the substrate.

9. The device of claim 8, wherein the pores of the porous layer extend completely therethrough to expose portions of the substrate along the sidewalls of the via hole.

10. The device of claim 9, wherein the pores of the porous layer further extend into the portions of the substrate along the sidewalls of the via hole.

11. The device of claim 1, further comprising:
a via insulating layer on sidewalls of the conductive via electrode between the conductive via electrode and the porous layer, wherein the porous layer has dielectric constant less than that of the via insulating layer.

12. The device of claim 11, wherein the porous layer and the via insulating layer respectively comprise a silicon oxide.

13. The device of claim 11, wherein the via insulating layer comprises a first via insulating layer, and further comprising:
a second via insulating layer on the sidewalls of the via hole between the porous layer and the substrate, wherein the porous layer has dielectric constant less than that of the second via insulating layer.

14. The device of claim 13, wherein the pores do not extend completely through the porous layer, and wherein the second via insulating layer comprises a portion of the porous layer through which the pores do not extend.

15. The device of claim 11, wherein the porous layer comprises portions of the substrate that define the sidewalls of the via hole.

16. The device of claim 1, further comprising:
at least one microelectronic component on a surface of the substrate outside the via hole, wherein the at least one microelectronic component is laterally spaced apart from the conductive via electrode by about 5 micrometers or less.

17. The device of claim 16, wherein the via hole and the conductive via therein are confined below the surface of the substrate including the at least one microelectronic component thereon.

18. The device of claim 16, further comprising:
one or more insulating interlayers on the surface of the substrate including the at least one microelectronic component,
wherein the via hole and the conductive via therein extend through at least one of the one or more insulating interlayers.

19. The device of claim 1, wherein the conductive via electrode comprises:
a barrier layer on the sidewalls of the via hole; and
a conductive layer on the barrier layer,
wherein the barrier layer comprises a material configured to reduce atomic diffusion of the conductive layer into the substrate.

20. The device of claim 1, wherein the conductive via comprises doped polysilicon or tungsten.

21. A multi-chip module, comprising:
a module substrate; and
a first microelectronic device on the module substrate;
wherein the first microelectronic device comprises a microelectronic device according to claim 1, and wherein the conductive via electrode provides an electrical connection between the first microelectronic device and the module substrate.

22. The module of claim 21, further comprising:
a second microelectronic device on the first microelectronic device,
wherein the conductive via electrode provides an electrical connection between the second microelectronic device and the module substrate.

23. The module of claim 22, wherein the module comprises a system in package (SIP), wherein one of the first and second microelectronic devices comprises a memory device, and wherein the other of the first and second microelectronic devices comprises a memory controller.

24. An electronic system, comprising:
a processor;
a memory;
a user interface; and
a bus configured to provide communication between the processor, the memory, and the user interface,
wherein at least one of the processor and the memory comprises a microelectronic device according to claim 1.

25. A microelectronic device, comprising:
a substrate including a via hole extending therethrough, wherein sidewalls of the via hole comprise a silicon oxide layer and a layer having a lower dielectric constant than that of the silicon oxide layer thereon; and
a conductive via electrode extending through the via hole between the sidewalls thereof such that the silicon oxide layer separates the conductive via electrode from the layer having the lower dielectric constant.

26. The device of claim 25, wherein the layer having the lower dielectric constant comprises a porous layer including a plurality of pores therein having respective pore sizes greater than that of the silicon oxide layer.

27. The device of claim 26, wherein the porous layer comprises a portion of the silicon oxide layer, and wherein the pores are sized sufficiently to reduce the dielectric content of the porous layer to less than that of the silicon oxide layer.

28. The device of claim 26, wherein the porous layer comprises a portion of the substrate.

29.-52. (canceled)
